(19) United States
(12) Patent Application Publication
(10) Pub. No.: US 2006/0105249 A1
(43) Pub. Date: May 18, 2006

(54) Exposure mask and method of manufacturing the same

(75) Inventors: Yasuyuki Kushida, Kawasaki (JP); Naoyuki Ishiwata, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/090,045

(22) Filed: Mar. 28, 2005

(30) Foreign Application Priority Data
Nov. 17, 2004 (JP) 2004-333380

(51) Int. Cl. G03C 5/00; G03F 9/00; G03F 1/00; G06K 9/00

(52) U.S. Cl. 430/5; 382/144; 430/30; 430/22

(57) ABSTRACT

A method of manufacturing an exposure mask, which has the steps of: obtaining the form data D₁ of device exposure patterns by applying optical proximity effect correction to the form data D₀ of device patterns; obtaining the form data D₂ of monitor exposure patterns, where the rising amount of corners is increased, number of the corners is reduced, or a side between the corners is extended comparing to the device exposure patterns; forming each exposure patterns on a transparent substrate by lithography; measuring the dimensions of the monitor exposure patterns; and ensuring the dimensions of the device exposure patterns by the dimensions of the monitor exposure patterns.

### CROSS-REFERENCE TO RELATED APPLICATIONS

This application is based on and claims priority of Japanese Patent Application No. 2004-333380 filed on Nov. 17, 2004, the entire contents of which are incorporated herein by reference.

### BACKGROUND OF THE INVENTION

1. Field of the Invention

The present invention relates to an exposure mask and a method of manufacturing the exposure mask.

2. Description of the Prior Art

In recent years, semiconductor devices such as an LSI have increasingly become higher integration, and exposure patterns of an exposure mask used in an exposure apparatus is fining with such higher integration. When the exposure patterns are made finer in this manner, patterns having shapes deformed from the planar shape of the exposure patterns are projected onto a wafer due to optical proximity effect. As such, in order to project device patterns having designed line widths and dimensions onto the wafer, OPC (Optical Proximity Correction) process, in which the optical proximity effect is taken account, is performed to the form data of the device patterns, and patterns obtained by this process is employed as exposure patterns.

Further, although some progresses such as shorter wave length of exposure light, higher NA of a projection lens, and improved resist process are made in the forefront of the exposure process in which the fine design rule is employed, exposure margin is very strict and line width fluctuation of the exposure patterns significantly affects the line widths of finished resist patterns.

Therefore, the line widths of the exposure patterns, to which the OPC process has been performed as described above, are generally measured by a CD-SEM (Scanning Electron Microscope) or the like after the patterns is formed in order to confirm whether or not the line widths are the same as calculated values in the OPC process.

Note that the following Patent Document 1 discloses technology to measure a plurality of points of fine patterns by the SEM.

[Patent Document 1] Japanese Patent Laid-open No. 11-251224 publication

### SUMMARY OF THE INVENTION

According to one aspect of the present invention, there is provided an exposure mask, comprising: a transparent substrate; a device exposure pattern formed in a device region of said transparent substrate, where a corner formed by a optical proximity effect being formed in at least one side of said device exposure pattern; and a monitor exposure pattern formed in a monitor region of said transparent substrate, where, as compared with said device exposure pattern, a rising amount of said corner of said monitor exposure pattern being increased, or the number of said corner of said monitor exposure pattern being reduced, or a side of said monitor exposure pattern between said corners is extended.

Further, according to another aspect of the present invention, there is provided a method of manufacturing an exposure mask, comprising the steps of: Obtaining a form data of a device exposure pattern, in which a corner is formed in at least one side, by performing an optical proximity effect correction for a form data of a device pattern; obtaining an exposure data of a monitor exposure pattern, where, as compared with said device exposure pattern, a rising amount of said corner of said monitor exposure pattern being increased, or the number of said corner of said monitor exposure pattern being reduced, or a side of said monitor exposure pattern between said corners is extended; patterning a film on a transparent substrate by lithography using each of said form data of said device exposure pattern and said monitor exposure pattern to form said device exposure pattern and said monitor exposure pattern; measuring a dimension of said monitor exposure pattern by using a dimension sizer; and ensuring a dimension of said device exposure pattern through the dimension of said monitor exposure mask by determining whether or not the dimension of said measured monitor exposure pattern falls within an allowable range of design dimension of said device exposure pattern.

Next, the operation of the present invention will be explained.

According to the method of manufacturing an exposure mask of the present invention, the monitor exposure pattern is formed in a manner where at least the corner thereof is made larger, the number of the corner is reduced, or a side of the corner is extended, and the dimension of the device exposure pattern is ensured by the dimension of the monitor exposure pattern.

When the corner of the monitor exposure pattern is made larger, it is possible to measure the dimension of the monitor exposure pattern while clearly recognizing the corner position, which prevents erroneous measuring points of the dimension. Further, since the measuring points of dimensions and the corners can be sufficiently separated by extending the side between the corners, it is possible to measure the dimension of the monitor exposure pattern without taking a rounded pattern near the corner, and thus the accuracy of dimension measurement improves. Then, since the length of the side is automatically extended by reducing the number of corners, dimension measurement accuracy can be improved as described above. According to these advantages, the present invention increases the reproducibility of dimension measurement value of the monitor exposure pattern, which in turn increases the accuracy of ensuring the line widths of the device exposure pattern.

### BRIEF DESCRIPTION OF THE DRAWINGS

FIG. 1 is an original layout of a general device pattern formed on a wafer;

FIG. 2 is an enlarged plan view of an exposure mask used when projecting the device pattern of FIG. 1;

FIG. 3 is a plan view of a monitor attached to a general CD-SEM;

FIG. 4 is an enlarged plan view of device exposure patterns displayed on the monitor of FIG. 3;

FIG. 5 is a plan view of a virtual exposure mask for improving the measurement accuracy of line widths of the device exposure patterns;

FIG. 6 is an enlarged plan view of device patterns in a first embodiment of the present invention;

FIG. 7 is an entire plan view of an exposure mask according to the first embodiment of the present invention;

FIG. 8 is a view for explaining an OPC process used in the first embodiment of the present invention;

FIG. 9 is a view for explaining a grid value of the OPC process used in the first embodiment of the present invention;

FIG. 10 is a view for explaining intervals of evaluating points of the OPC process used in the first embodiment of the present invention;

FIG. 11 is a flowchart showing a method of manufacturing the exposure mask according to the first embodiment of the present invention;

FIG. 12 is a schematic view for explaining step S1 of the method of manufacturing the exposure mask according to the first embodiment of the present invention;

FIG. 13 is a schematic view for explaining sub-step P1 of the method of manufacturing the exposure mask according to the first embodiment of the present invention;

FIG. 14 is a view where a plurality of the form data of monitor exposure patterns obtained in the first embodiment of the present invention;

FIG. 15 is a plan view for explaining the minimum value of a distance between corners of the monitor exposure patterns;

FIG. 16 is a table obtained by calculating the size of rectangle E in each form data of a plurality of monitor exposure patterns in the first embodiment of the present invention;

FIG. 17 is a plan view of an abnormal image obtained by projecting the monitor exposure patterns in the first embodiment of the present invention;

FIG. 18 is a view showing a result of light intensity simulation in the first embodiment of the present invention;

FIGS. 19A to 19J are sectional views showing the method of manufacturing the device exposure patterns and the monitor exposure patterns in the order of process in the first embodiment of the present invention;

FIG. 20 is a plan view of a monitor when measuring the line widths of the monitor exposure patterns in the first embodiment of the present invention;

FIG. 21 is a constitution view of an EB exposure apparatus used in the first embodiment of the present invention;

FIGS. 22A to 22D are sectional views showing the method of manufacturing the device exposure patterns and the monitor exposure patterns in the order of process in a second embodiment of the present invention; and

FIGS. 23A to 23E are sectional views showing the method of manufacturing the device exposure patterns and the monitor exposure patterns in the order of process in a third embodiment of the present invention.

### DETAILED DESCRIPTION OF THE PREFERRED EMBODIMENTS

### (1) Preliminary Explanation

Preliminary explanation of the present invention will be made before explaining the embodiments of the present invention.

The OPC process is roughly divided into a rule-based OPC and a model-based OPC. Since the correction is made by optical simulation in the model-based OPC, correction accuracy in the model-based OPC is higher than that in rule-based OPC, which makes correction by referring the finite table constructed from pattern dimension and distance between the patterns. As such, model-based OPC is preferable for the forefront devices whose design rule is fine.

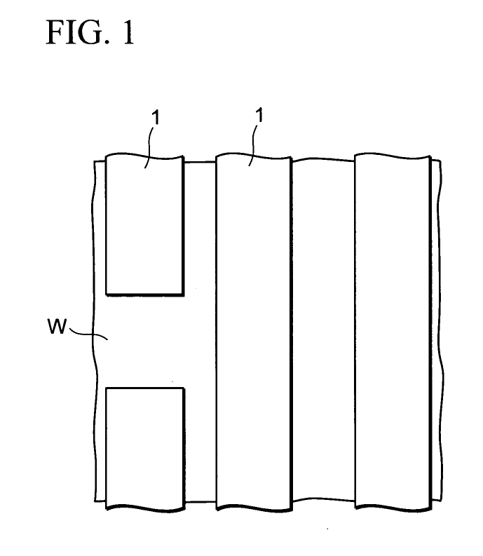

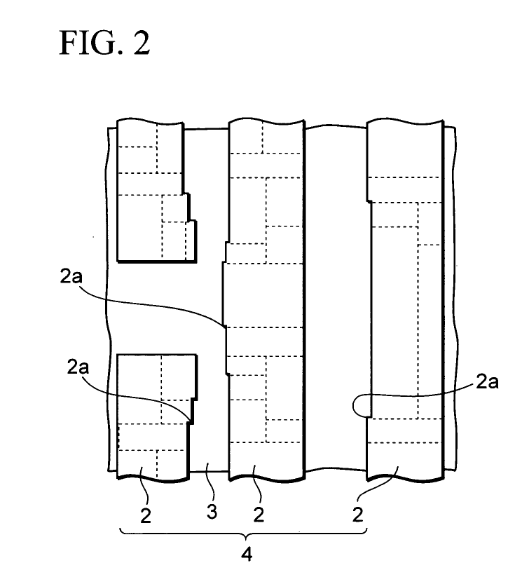

FIG. 1 is the original layout of a device pattern 1 such as wirings and gates formed on a wafer W. On the other hand, FIG. 2 is the enlarged plan view of an exposure mask 4 used for projecting the device pattern 1. The exposure mask 4 is made in such a manner that device exposure patterns 2, to which optical proximity effect correction by the model-based OPC has been applied, is formed on a quartz substrate 3. Then, fine corners 2a caused by the OPC process are formed in many places of the device exposure pattern 2, and it can be understood that the shape of the device exposure pattern 2 is made complicated as compared with the device pattern 1 in FIG. 1. Further, the device exposure pattern 2 is formed by etching a light-shielding film while using a resist pattern as a mask, the resist pattern is exposed by EB (Electron Beam) exposure, for example, and each rectangle shown by broken lines in the drawing is equivalent to the exposure size of one shot.

In manufacturing such an exposure mask 4, the line width (dimension) of the exposure pattern 2 is actually measured by the CD-SEM or the like to ensure the dimensional precision of the device exposure pattern 2.

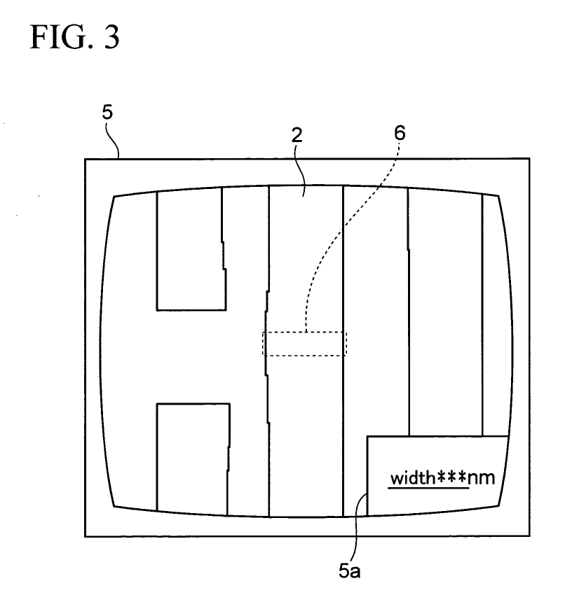

FIG. 3 is a plan view of a monitor 5 attached to the CD-SEM. When measuring the line widths, the SEM image of the device exposure pattern 2 is shown on the monitor 5, and an operator drags a mouse (not shown) to decide a slit 6 that becomes a measuring region of a line width. Then, the width of the device exposure pattern 2 is measured at measurement point arrayed at 20 to 30 points in lengthwise directions (vertical directions of the drawing) in the slit 6, and an average value of the measurement points is displayed as the width of the slit 6 in a partial region 5a of the monitor 5.

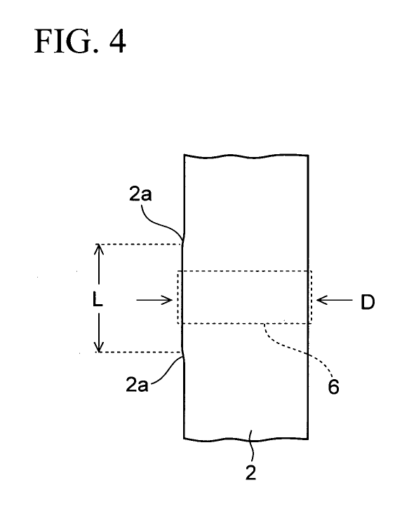

FIG. 4 is the enlarged plan view of the device exposure pattern 2 displayed on the monitor 5. Although corners 2a caused by the OPC process rise by the angle of 90 degrees in exposure data, their shapes actually become rounded due to etching or the like performed in forming the exposure pattern 2. In addition, since the corners 2a are originally very fine as small as about 2 nm, it is difficult to distinguish on the monitor 5 where the corners 2a are present in the exposure pattern 2 if the shapes are rounded as described above. As a result, the slit 6 may overlap the corners 2a despite that the width of the exposure pattern 2 of D area between the two corners 2a needs to be measured, and there occurs a danger that the width including the corners 2a will be measured, and the measurement of the exposure pattern 2 becomes inaccurate. Therefore, this raises some possibility of including an individual difference of an operator in the way of setting the slit, and the reproducibility of the measurement result of line width becomes worse.

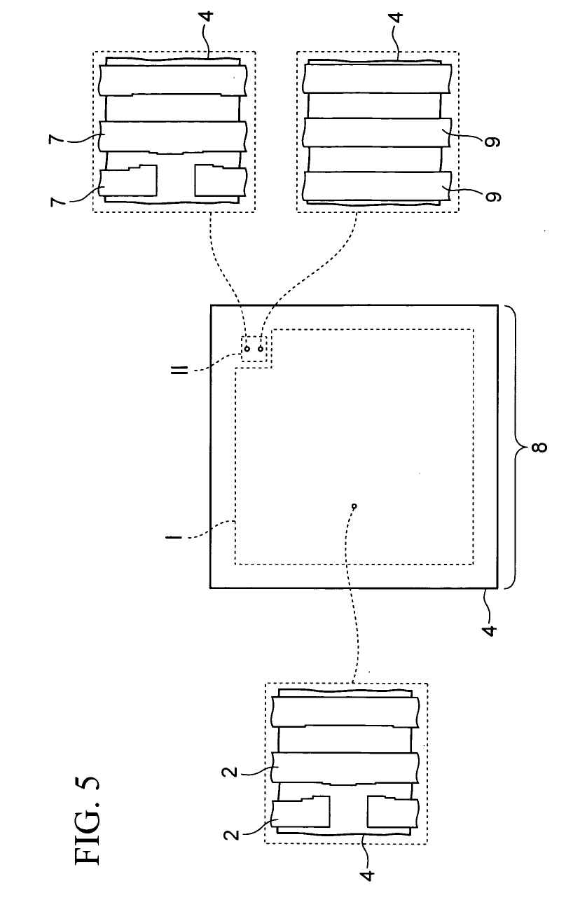

FIG. 5 is the plan view of a virtual exposure mask 8 for overcoming such problems.

The exposure mask 8 has the quartz substrate 4, and the quartz substrate 4 is partitioned into a device region I and a monitor region II. The device exposure pattern 2 to which the OPC process has been applied are formed on the device region I, and the projected image of the device exposure patterns 2 corresponds to the planar shape of the device pattern 1 of FIG. 1.

On the other hand, on the monitor region II, monitor exposure pattern 9 of a line-and-space shape to which the OPC process is not applied are formed, and real patterns 7 having the same shape as the device exposure pattern 2 are also formed for reference.

Then, in the exposure mask 4, the line widths of the monitor exposure pattern 9 in which corners by the OPC process have not been formed are measured instead of the device exposure pattern 2, and their measurement result indirectly ensures the line widths of the device exposure pattern 2 on the assumption that the measurement result approximates the line widths of the device exposure patterns 2.

However, since the density of patterns is different in the device exposure pattern 2 and the monitor exposure pattern 9, the patterns 2 and 9 have different etching rates in lateral direction in etching at the time of patterning the patterns 2 and 9. Furthermore, in the case of performing EB (Electron Beam) exposure for resist pattern that is served as etching mask when patterning the patterns 2 and 9, a plurality of rectangular shots are arrayed on one pattern. However, since the shots size and the way of arraying the shots differs between each patterns 2 and 9, finished planer shape also differs between each patterns 2 and 9. Therefore, deviation occurs between the line widths of the patterns 2 and 9 and it becomes impossible to accurately ensure the line widths of the device exposure pattern 2 by the line widths of the monitor exposure pattern 9. Moreover, since the line width deviation becomes more conspicuous as the pattern becomes finer, the line width deviation becomes a factor of preventing microfabrication of semiconductor devices.

It might be considered that device exposure pattern, which does not undergo the OPC process, is used as the monitor exposure pattern 9. However, if the OPC process is not applied to the pattern, such a situation arises where the projection image of the monitor exposure pattern 2 deforms due to optical proximity effect, and fine island-like images that are separate from the pattern are projected on a photoresist. If this is the case, portion of the photoresist corresponding to the island-like image is stripped from the wafer during development and adheres onto the device region of the wafer, and there is a danger of causing a defect in finished semiconductor devices.

In view of these problems, the inventors of the present invention have come up with the following embodiments of the present invention.

### (2) First Embodiment

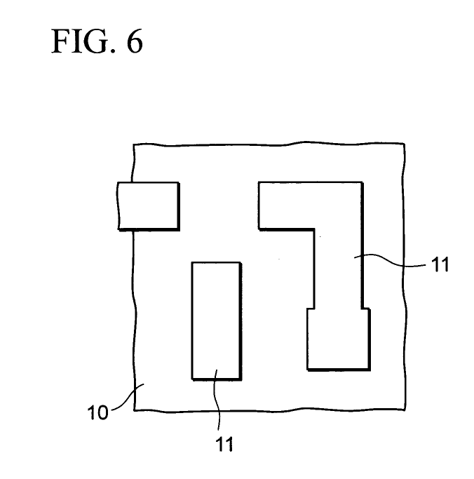

FIG. 6 is the enlarged plan view of device pattern 11 formed on a silicon substrate 10. The device pattern 11 is a component that constitutes a semiconductor device, and wirings, gate electrodes, or the like are its example.

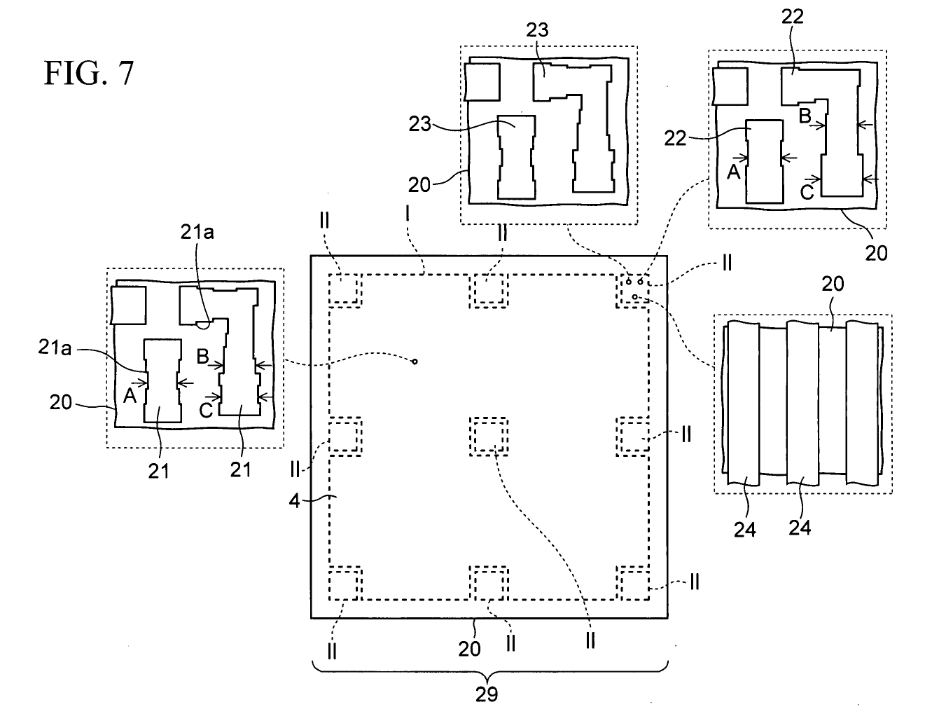

On the other hand, FIG. 7 is the entire plan view of the exposure mask according to this embodiment, which is used for forming the device pattern 11 in a photolithography process. The exposure mask 29 has an optically transparent quartz substrate (transparent substrate) 20 that is partitioned into a device region I and nine monitor regions II.

In the device region I, a device exposure pattern 21 is formed on the quartz substrate 20, and the projected image of the device exposure pattern 21 corresponds to the planar shape of the above mentioned device pattern 11. The OPC process is applied to the device exposure pattern 21, and a plurality of corners 21a caused by the process are formed in the pattern 21.

On the other hand, in the monitor region II, a monitor exposure pattern 22 is formed on the quartz substrate 20. In addition, real pattern 23 having the same shape as the device exposure pattern 21 and line-and-space pattern 24 (hereinafter referred to as L/S patterns 24) are formed in the monitor region II for reference.

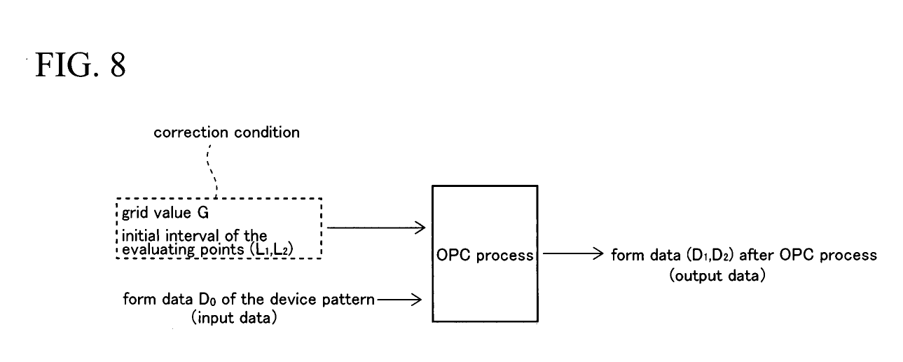

FIG. 8 is the view for explaining the OPC process. As shown in FIG. 8, input data of the OPC process is form data D₀ of the device pattern, and a grid value G and initial interval (L₁, L₂) between evaluating points are used as correction conditions. A type of the OPC process is not limited, but it is preferable to employ the model-based OPC in this embodiment.

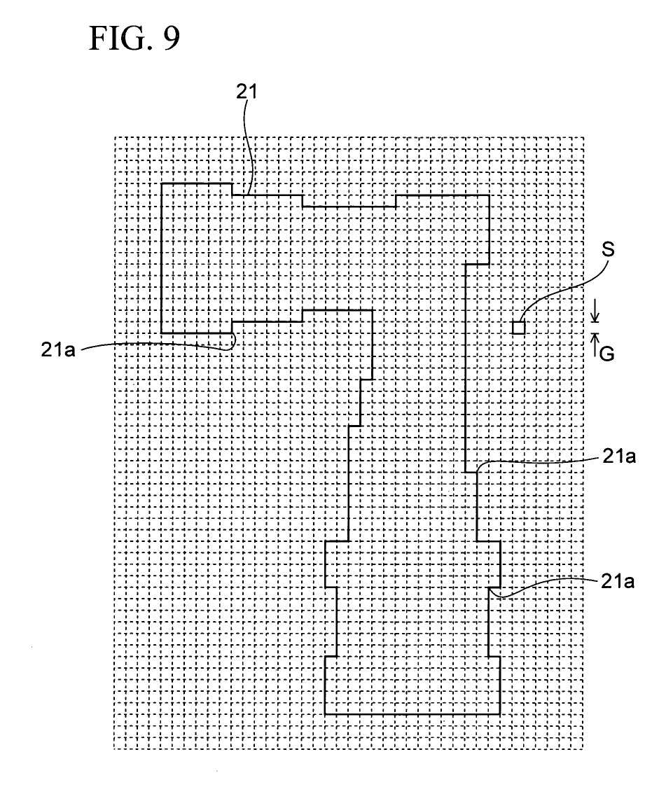

FIG. 9 is the view for explaining the grid and the grid value G. The grids are vertexes of each small square S dividing a plane, and the grid value G represents the length of a side of the small square S. In the OPC process, vertexes of the device exposure pattern 21 after the OPC are set to coincide with the grids, so that the device exposure pattern 21 becomes such a shape that goes along the side of the above-described small squares. In short, the grid value G is the minimum unit in extending sides and applying the corners 21a, and correction becomes rougher as the grid value becomes larger.

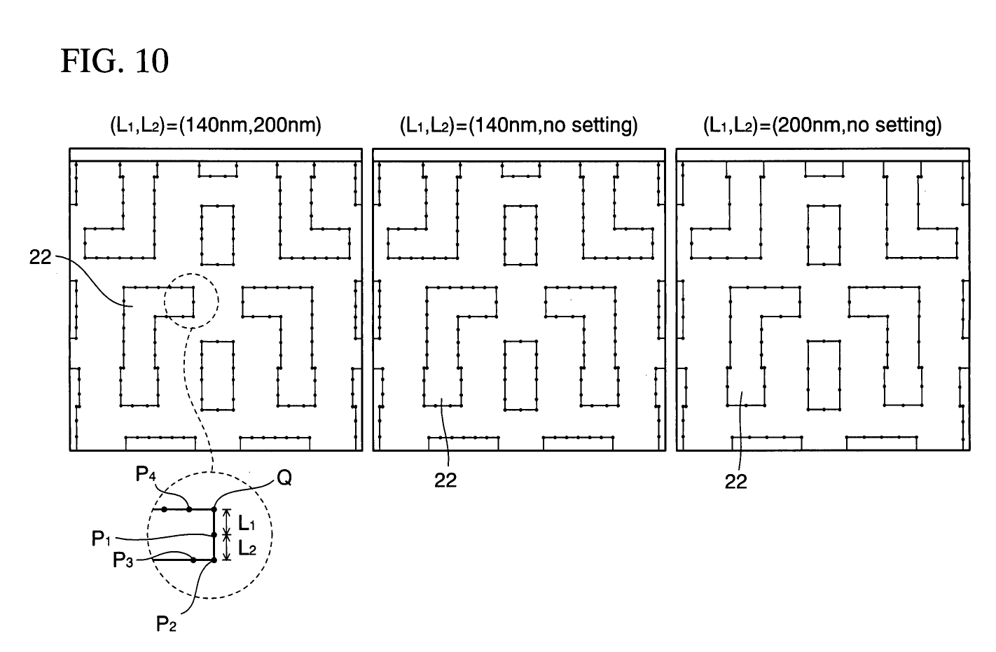

FIG. 10 is the plan view for explaining the evaluating point and their initial interval. Evaluating points Pn are points that exist on the vertexes or on the sides of the pattern 22 and are points at which the pattern line widths are corrected by calculating the affect of optical proximity effect. Then, the initial interval (L₁, L₂) of evaluating points are a pair of distance L₁ and L₂, where the L₁ is the interval between vertex Q before the OPC process is performed and an adjacent evaluating point P₁, and the L₂ is the interval between the evaluating point P₁ and the next evaluating point P₂. Evaluating points P₃, evaluating point P₄ and so on further than the evaluating point P₂ are automatically set depending on how evaluating points around them rise.

FIG. 10 shows how the evaluating points rise when (140 nm, 200 nm), (140 nm, no setting), and (200 nm, no setting) are employed as the initial intervals (L₁, L₂) of evaluating points. It should be noted that these numerical values are values on the mask, and there value becomes ¼ of the above on the wafer. Further, in these conditions, the one whose second component of the initial intervals (L₁, L₂) of evaluating points is “no setting” means that the second component L₂ has been left blank in an input screen of the OPC process. In such a case, the OPC process is performed assuming that the value of the first component L₁ is substituted into the second component L₂.

As shown in FIG. 10, when either one or both of the components of the initial intervals (L₁, L₂) of evaluating point is made larger, the number of evaluating points reduces and the accuracy of correction becomes rougher.

In this embodiment, the exposure mask is manufactured as follows by using such OPC process.

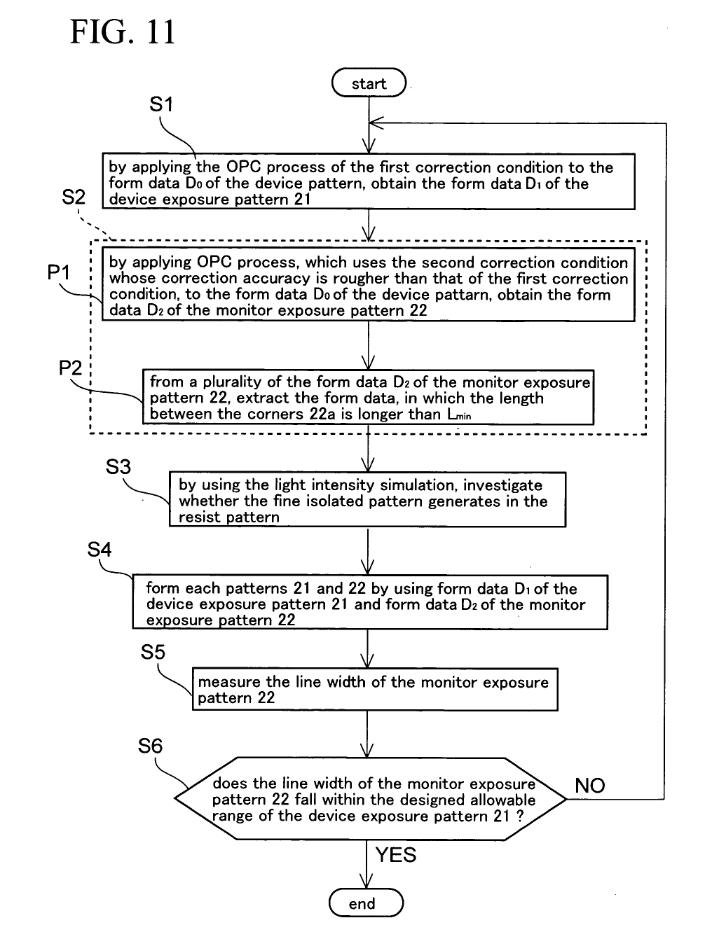

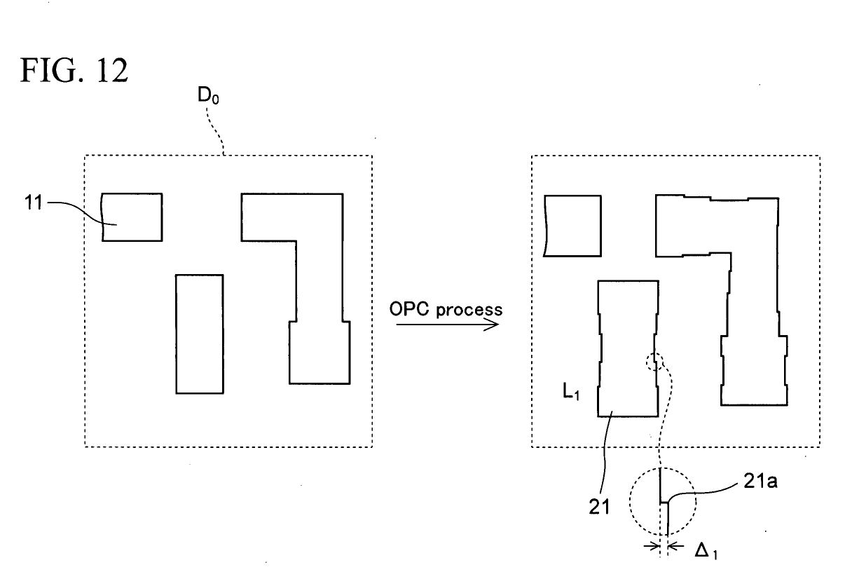

FIG. 11 is the flowchart showing the method of manufacturing the exposure mask according to this embodiment, and FIG. 12 is the schematic view for explaining step S1 of the flowchart.

In the first step S1, by applying the OPC process to the form data D₀ of the device patterns 11, form data D₁ of the device exposure patterns 21 for which optical proximity effect is taken in consideration is obtained, as shown in FIG. 12. Note that each form data D₀ and D₁ is a digital value and invisible, but FIG. 12 shows visualized form data D₀ and D₁ by allowing the actual patterns 11 and 12 to attach to each form data D₀ and D₁ for easy understanding.

Since the device exposure patterns 21 are patterns for projecting actual device patterns such as the gate electrodes and wirings, it is preferable to employ conditions that make correction accuracy as fine as possible as the correction conditions (grid value, initial interval of evaluating points) of the OPC process in order to increase processing accuracy of the device patterns. For this reason, the condition, in which the grid value is set as 2 nm and initial intervals (L₁, L₂) as (140 nm, 200 nm), are employed as the correction condition in this embodiment. In the following, this correction condition will be referred to as the first correction condition.

After completing step S1 in this manner, process proceeds to step S2, which is divided into sub-step P1 and sub-step P2.

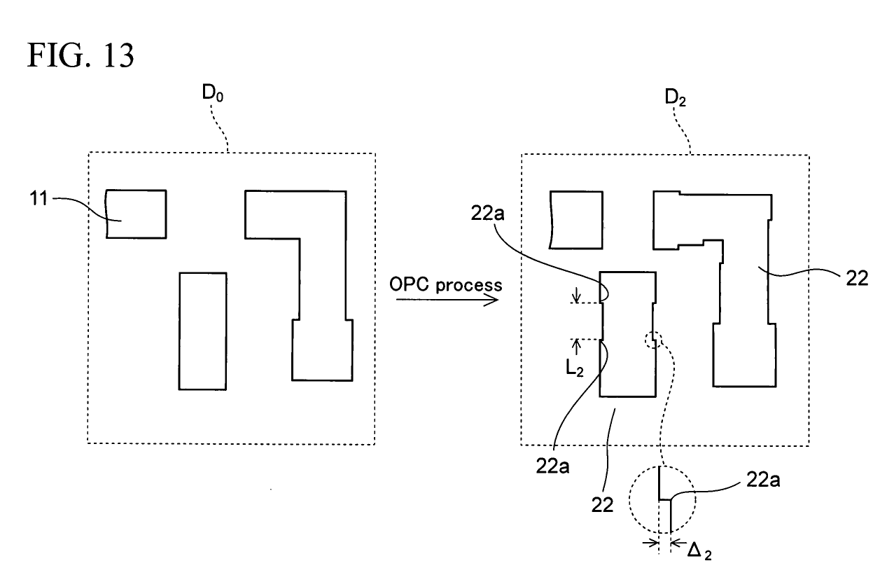

FIG. 13 is the schematic view for explaining sub-step P1 out of the sub-steps.

In sub-step P1, the OPC process is applied to the form data D₀ of the device patterns 11 by using second correction condition whose correction accuracy is rougher than the above-described first correction condition, and thus form data D₂ of the monitor exposure patterns 22 is obtained.

When such rough second correction condition is employed, the rising amount Δ₂ of corner 22a becomes larger than the rising amount Δ₁ of corner 21a in the device exposure patterns 21 (see FIG. 12). Furthermore, the length L₂ of the side between adjacent corners 22a is also extended longer than length L₁ in the device exposure patterns 21. Additionally, the number of the corners 22a reduces as compared with the number of the corners 21a of the device exposure patterns 21.

Although only one form data D₂ may be calculated by single second correction condition, it is preferable to calculate a plurality of form data D₂ by using a plurality of the second correction conditions. In view of this, 12 kinds of correction conditions shown in the table 1 below are employed as the second conditions in this embodiment, and the form data D₂ is calculated for each of the conditions.

TABLE 1
Second correction conditions

| Grid value G | Interval of evaluating points (L₁, L₂) |
|---|---|
| 2 | (140, 200) |
| 2 | (140, no setting) |
| 2 | (200, no setting) |
| 12 | (140, 200) |
| 12 | (140, no setting) |
| 12 | (200, no setting) |
| 16 | (140, 200) |
| 16 | (140, no setting) |
| 16 | (200, no setting) |
| 20 | (140, 200) |
| 20 | (140, no setting) |
| 20 | (200, no setting) |
| | Unit: nm |

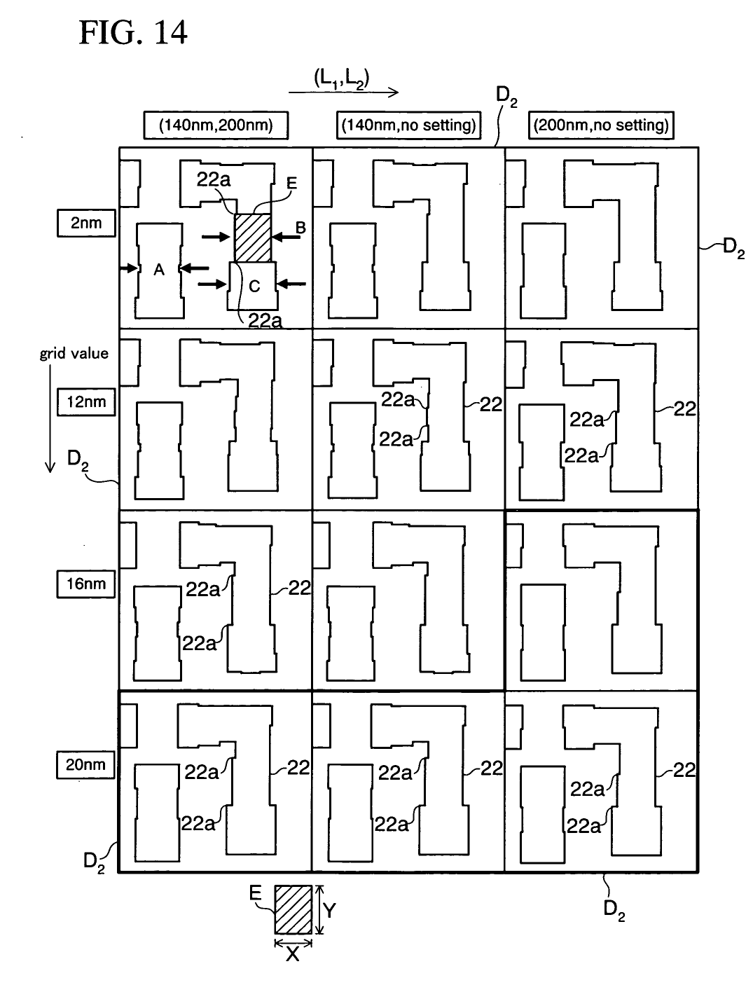

FIG. 14 is the view obtained by visualizing a plurality of the form data D₂ of the monitor exposure patterns 22. In this drawing, a column direction is labeled by the initial intervals (L₁, L₂) and a row direction is labeled by the grid value G. Further, in FIG. 14, the upper left form data is the one obtained by setting the grid value to 2 nm and the initial intervals (L₁, L₂) to (140 nm, 200 nm), which is the same as the form data D₁ of the device exposure patterns 21 calculated in the step S1.

As shown in FIG. 14, it can be understood that the lengths of sides between adjacent corners 22a varies depending on the second correction conditions. Further, the rising amount of the corners 22a caused by the correction also varies depending on the second correction conditions.

Thus, the fundamental processing of sub-step P1 ends.

Incidentally, since the line width of the monitor exposure patterns 22 is actually measured later, the monitor exposure patterns 22 needs to be formed into a shape that facilitates the measurement of the line width as much as possible.

As explained in FIG. 4, when performing line width measurement by the CD-SEM, the operator defines the slit 6 by dragging the mouse not to overlap the corners 2a caused by the OPC process. At this time, when the corners 2a are small, it is difficult to confirm their presence on the screen, and there is a danger that the slit 6 will include the corners 2a. Therefore, it is preferable to make the corners as large as possible in order to reduce the error in the measurement.

Further, when the side L between the corners 2a on one side of the pattern is elongated, the slit 6 is got away from the corner 2a, and hence it becomes easier to eliminate the affect of the corners 2a from the measurement result.

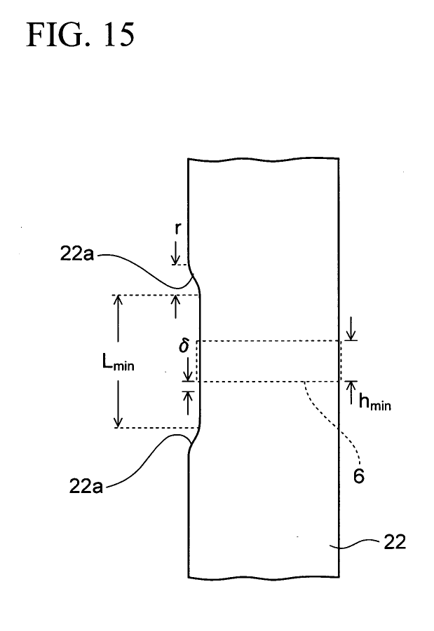

FIG. 15 is the plan view for explaining the minimum value Lₘᵢₙ of the length between the corners 22a, which is necessary for effectively reducing the affect of the corners 22a.

Using the minimum length hₘᵢₙ of the slit 6 that can be set by the CD-SEM, alignment error δ between the slit 6 and the pattern 22a, and rounding amount r, The minimum value Lₘᵢₙ is expressed as follows: Lₘᵢₙ=hₘᵢₙ+2δ+2r.

Note that the rounding amount r of the corner of pattern 22 represents the length of a portion where the line width of the pattern 22 changes near the corner 22a of the pattern 22, as shown in FIG. 15.

In this embodiment, these parameters are set as: hₘᵢₙ=100 nm; δ=50 nm; and r=50 nm, and the minimum value Lₘᵤₙ is set to 300 nm.

In the next sub-step P2, in order to extract form data D₂ whose side length between the corners 22a at the measurement points A, B, and C is longer than the Lₘᵢₙ among many form data D₂ obtained in FIG. 14, the size of the rectangle E in each form data D₂ is calculated for each data D₂. Note that width X of the rectangle E is defined by the line widths of the pattern 22 at each measurement point A, B and C, and length Y of the rectangles E is defined by the minimum distance between the corners 22a at each measurement point A, B and C.

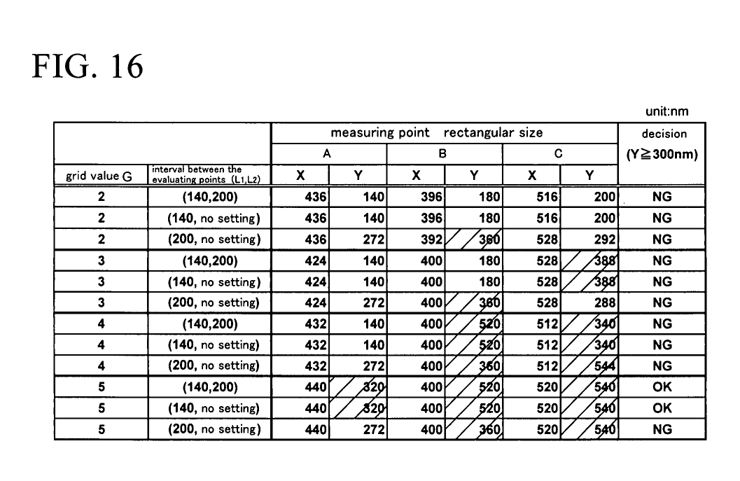

FIG. 16 is the table obtained by calculating the size of the rectangle E for each of a plurality of the form data D₂.

In FIG. 16, Y having Lₘᵢₙ (=300 nm) or more are hatched. As shown in this table, ones that satisfies Y≧Lₘᵢₙ at all measurement points A, B and C are limited to two cases where G=20 nm and (L₁, L₂)=(140 nm, 200 nm) are employed and the case where G=20 nm and (L₁, L₂)=(140 nm, no setting) are employed as the second correction conditions. However, as shown in FIG. 16, a rectangular size obtained is the same when any one of these two correction conditions is employed. Therefore, in the following, only the form data D₂ obtained by one of the above-described correction conditions, which is G=20 nm and (L₁, L₂)=(140 nm, no setting), is extracted.

In the form data D₂ extracted as above, the length Y of the rectangle E and the size of the corner 22a are extended as compared with those of the device exposure pattern 21. This is because the correction accuracy of the above-described second correction condition is rougher than the first correction condition used in obtaining the device exposure patterns 21, and because the number of vertexes of the monitor exposure pattern 22 reduced than that of the device exposure pattern 21.

This completes sub-step P2, and the process proceeds to the next step S3.

In the above-described sub-step S2, as shown in FIG. 14, various kinds of the form data D₂ of monitor exposure pattern 22 was obtained by varying the second correction conditions, and the form data D₂ that facilitates the line width measurement was extracted from many form data D₂. However, since this form data D₂ was obtained by making the correction accuracy of the OPC process rougher, there are cases where an image, which is obtained by projecting the monitor exposure pattern 22 corresponding to the form data D₂ by the exposure apparatus, becomes an extremely abnormal image due to optical proximity effect.

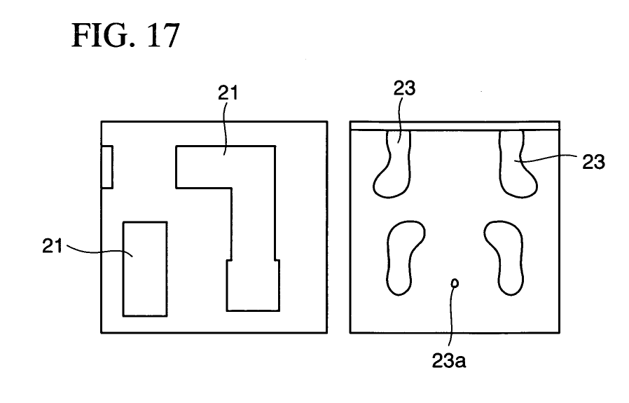

FIG. 17 is the plan view showing an example of such an abnormal image.

The left view of FIG. 17 is the plan view of the device exposure pattern 21 to which the OPC process does not performed, and the right view is the plan view of resist pattern 23 on the wafer, which is obtained by lithography using this exposure pattern 21.

As shown in the drawing, the planar shape of the resist patterns 23 deviate significantly from the device exposure patterns 21, and a fine isolated pattern 23a is formed in the resist pattern 23. Consequently, the fine isolated pattern 23a is stripped from the wafer and adheres onto the device pattern in the cleaning process or the like, and there is a danger to make the semiconductor devices defective.

In view of this, in step S3, it is investigated whether the fine isolated pattern generates in the resist pattern obtained from each of the monitor exposure pattern 22 shown in FIG. 14 by light intensity simulation using a computer.

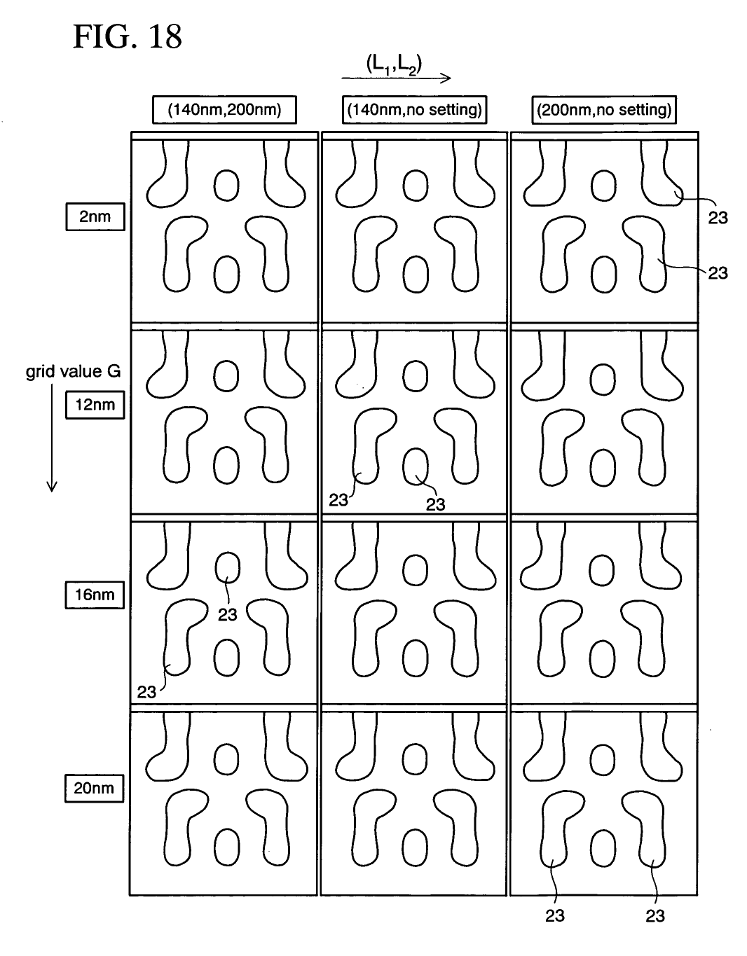

FIG. 18 is the images of the resist patterns 23 obtained by the light intensity simulation. In the drawing, the column direction is labeled by the initial intervals (L₁, L₂) and the row direction is labeled by the grid values G. Further, in this light intensity simulation, the transmittance of the translucent monitor exposure pattern 22 was set to 6.0% to ArF excimer laser beam having the wavelength of 193 nm. Furthermore, exposure wavelength of 193 nm, numerical aperture (NA) of 0.75, illumination aperture (a) of 0.85, and ½ zonal illumination were employed as exposure condition.

As shown in FIG. 18, the aforementioned fine isolated pattern, resolution defect, or extreme narrow pattern does not occur in any correction conditions. Therefore, it can be determined that device failure due to the strip of the resist pattern does not occur, even when the monitor exposure pattern 22, that is formed using the form data D₂ extracted in the sub-step P2, is used in the photolithography.

Up to this, step S3 competes and the process proceeds to step S4.

In step S4, the form data D₁ of the device exposure patterns 21, which has been obtained on step S1, and the form data D₂ of the monitor exposure patterns 22, which has been extracted on step S2, are used, and the patterns 21 and 22 are formed with the plan layout as shown in FIG. 7.

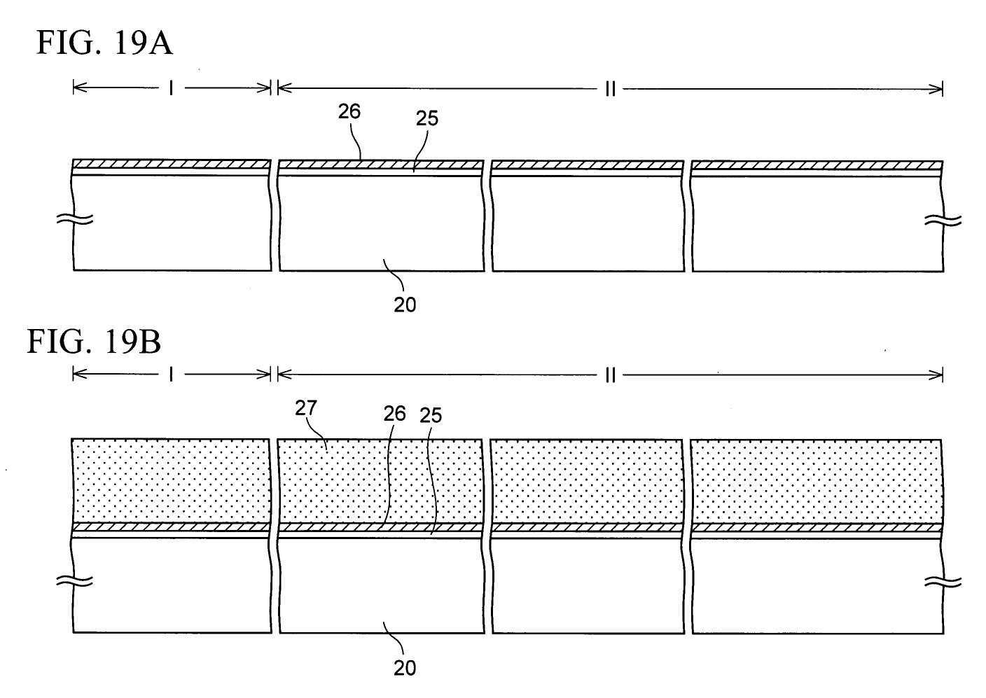

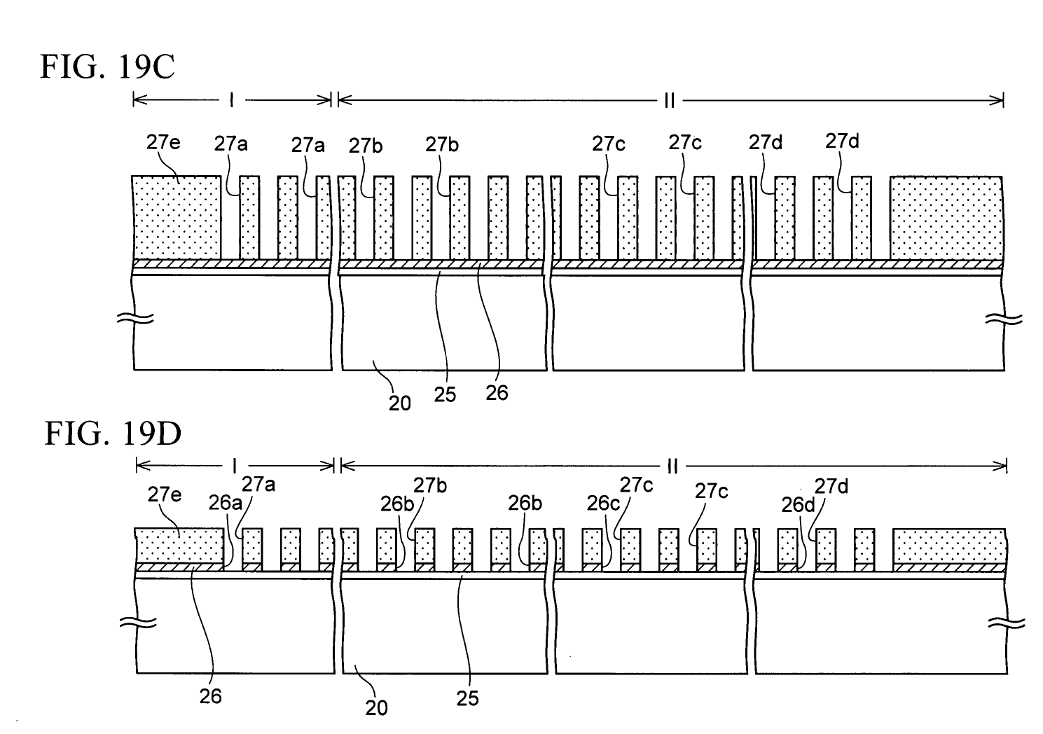

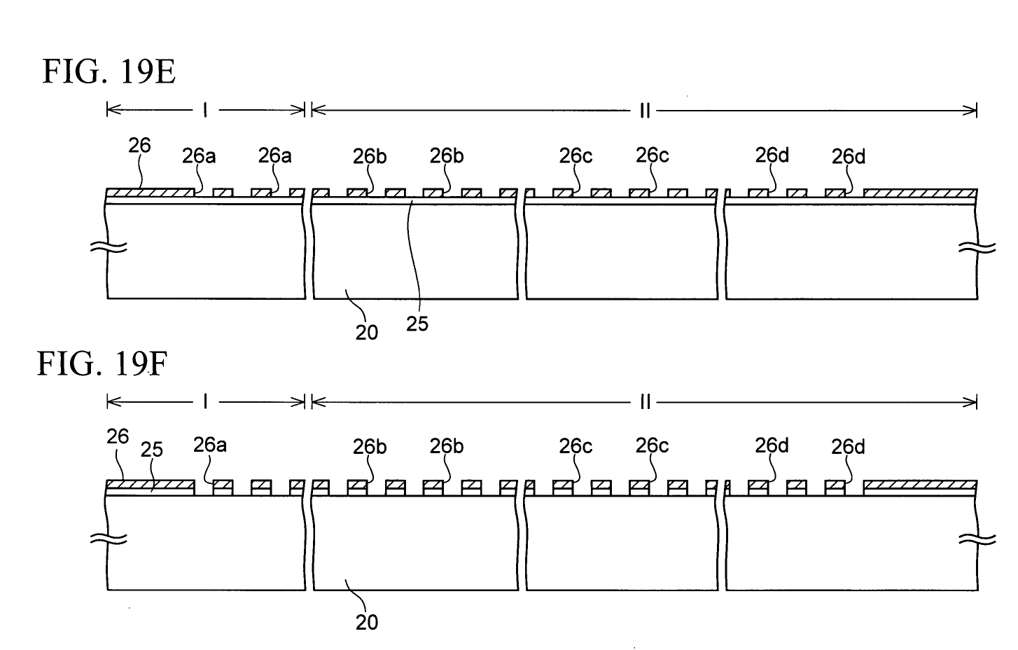

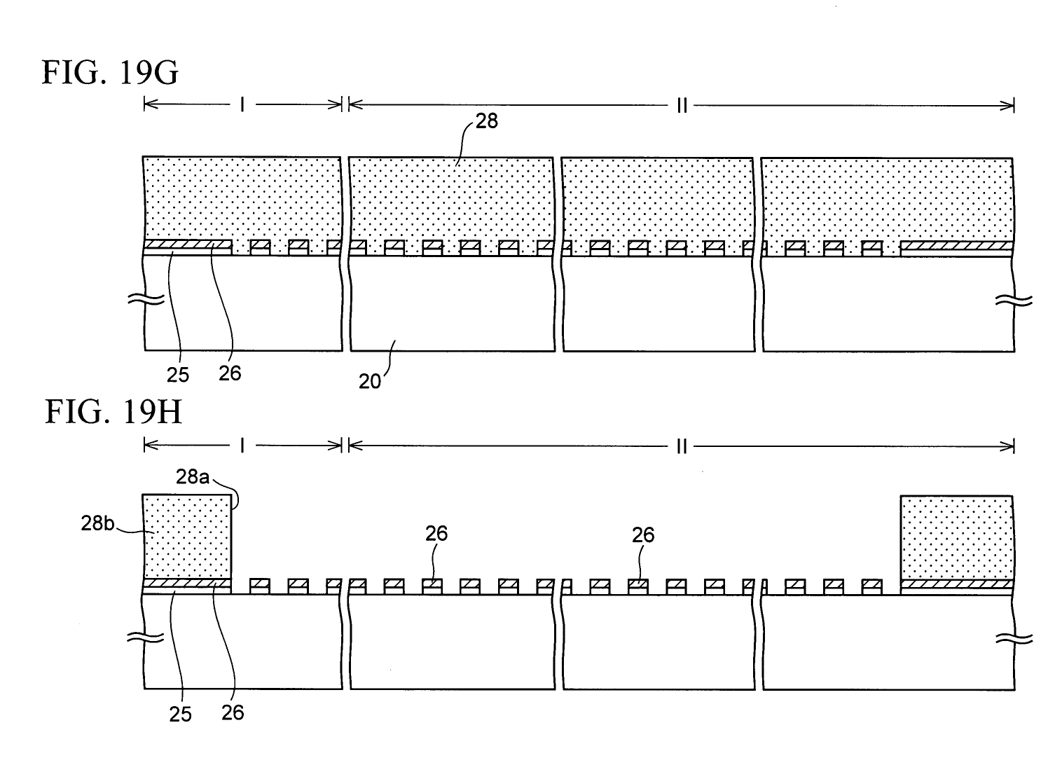

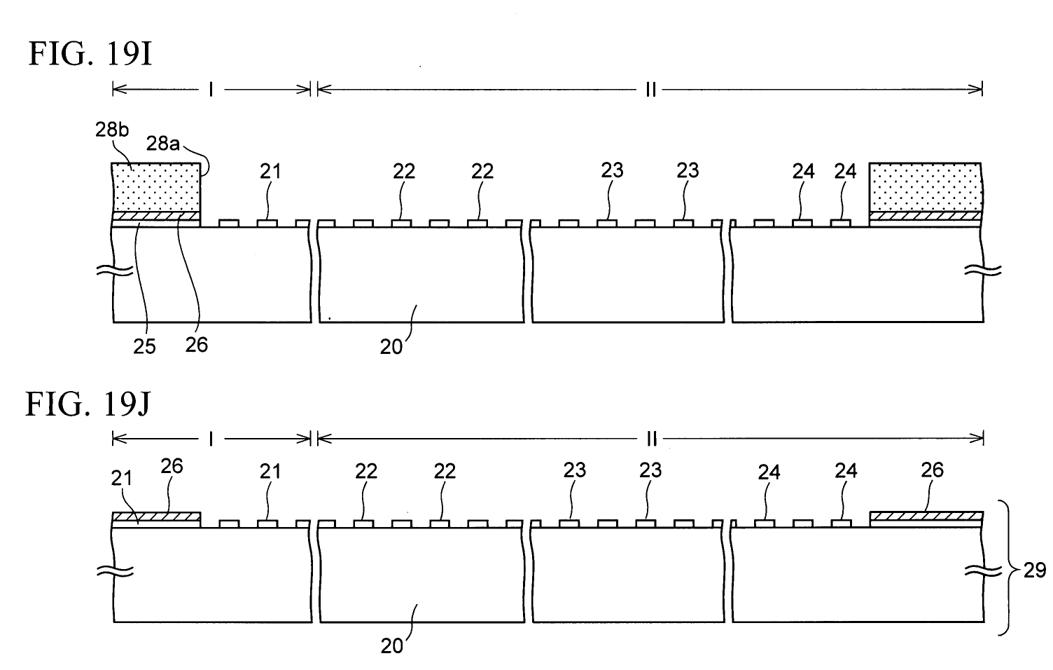

FIGS. 19A to 19J are the sectional views showing the method of manufacturing the patterns in the order of process.

First, description will be made for a process until the sectional structure shown in FIG. 19A will be obtained.

A MoSiN (molybdenum-silicide nitride) layer is formed to the thickness of about 65 nm by a sputtering method on the quartz substrate 20 having one side length of 6 inches and the thickness of 0.25 inch, and the MoSiN layer is used as a translucent phase shifter layer 25. Note that the constituent material of the phase shifter layer 25 is not limited to molybdenum-silicide compound such as molybdenum-silicide nitride, but may be chromium compound such as chromium oxide.

Next, a chromium (Cr) layer and a chromium oxide (CrₓO_{y}) layer are formed to the thickness of about 59 nm in this order on the phase shifter layer 25, and these layers are used as a light-shielding layer 26.

Subsequently, as shown in FIG. 19B, a first positive type electron beam resist 27 is formed to the thickness of about 400 nm on the light-shielding layer 26 by a spin coating method.

Note that the above-described quartz substrate 20, phase shifter layer 25, and light-shielding layer 26 are called as a mask blank in combination. The mask blank may be purchased from the manufacturer and following process may be performed for this mask blank.

In the next process, the above-described electron beam resist 27 is exposed by using the EB exposure apparatus.

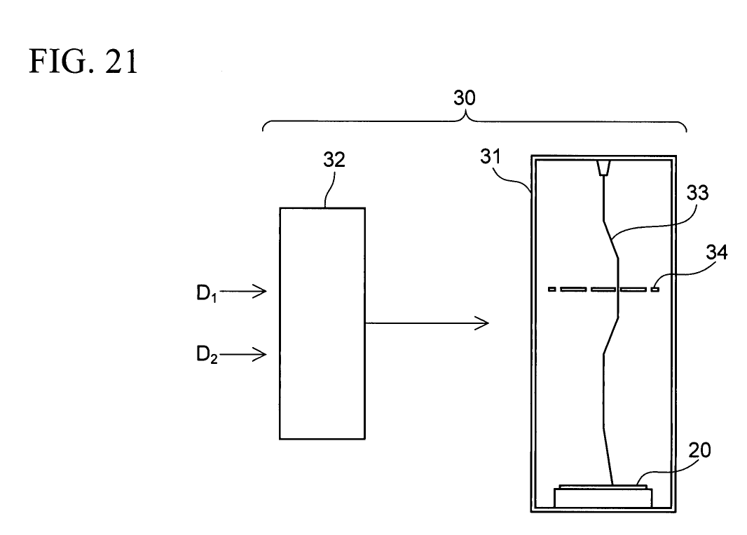

FIG. 21 is the constitution view of the EB exposure apparatus 30. To perform exposure, the quartz substrate 20 is carried into an electronic optical system column 31 of the EB exposure apparatus 30, and the inside of the column 31 is decompressed to a predetermined pressure. After that, the form data D₁ of the device exposure patterns 21 and the form data D₂ of the monitor exposure patterns 22, which have been described above, are input to a control section 32. Then, based on the form data D₁ and D₂, electron beam 33 whose sectional shape is shaped in a rectangle by a mask 34 is deflected to expose the first positive electron beam resist 27.

Then, by developing the first positive type electron beam resist 27 after exposure, a first resist pattern 27e including first to fourth windows 27a to 27d are obtained as shown in FIG. 19C.

Subsequently, as shown in FIG. 19D, the light-shielding layer 26 is etched using the first resist pattern 27e as a mask by plasma etching using chlorine-based gas as etching gas, and first to fourth openings 26a to 26d are formed in the light-shielding layer 26 under the first to fourth windows 27a to 27d. In this plasma etching, the upper surface of the first resist pattern 27e is etched, and the thickness of the first resist pattern 27e is reduced as shown in the drawing.

After that, as shown in FIG. 19E, the first resist pattern 27e is removed by oxygen ashing, and wet cleaning is performed for removing foreign objects.

Next, as shown in FIG. 19F, the phase shifter layer 25 is patterned by plasma etching using fluorine-based gas as etching gas while the light-shielding layer 26, in which the first to fourth openings 26a to 26d are formed, is used as an etching mask.

Subsequently, as shown in FIG. 19G, a second positive type electron beam resist 28 is formed to the thickness of about 400 nm on the entire surface by the spin coating method.

Next, as shown in FIG. 19H, by developing the second positive type electron beam resist 28 after exposing the resist by using the EB exposure apparatus, a second resist pattern 28b including a large fifth window 28a corresponding to a chip region is formed.

Next, as shown in FIG. 19I, the light-shielding layer 26 exposed from the fifth window 28a of the second resist pattern 28 is selectively removed by the plasma etching using chlorine-based gas as etching gas. Then, the phase shifter layer 25, left under the fifth window 28a without being etched, is made into the translucent device exposure patterns 21, the monitor exposure pattern 22, the real pattern 23, and the L/S pattern 24.

Thereafter, the second resist pattern 28b is removed by oxygen ashing, and a basic structure of an exposure mask 29 shown in FIG. 19J is completed.

The exposure mask 29 is a half-tone phase shift mask, in which each of the translucent exposure patterns 21 to 24 functions as the phase shifter, and the phase of exposure light passed through the patterns is shifted by 180 degrees as compared with the exposure light passed through the quartz substrate 20.

Further, the wide light-shielding layer 26 is left on the rim of the exposure mask 29, which prevents leaked light that is generated in performing exposure to the wafer (not shown), from entering the chip region.

Up to this, step S4 is completed and the process proceeds to step S5.

In step S5, the line width of the monitor exposure pattern 22 is measured by the dimension sizer in order to indirectly ensure the line width (dimension) of the device exposure pattern 21 fabricated in step S4. As the dimension sizer, the present embodiment uses the CD-SEM including the monitor 5 as shown in FIG. 3.

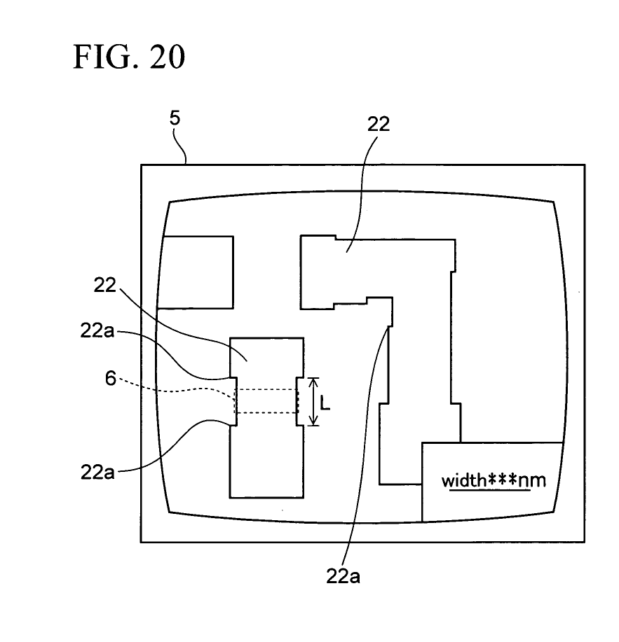

FIG. 20 is the plan view of the monitor 5 when measuring the line width of the monitor exposure pattern 22.

The monitor exposure pattern 22 was formed by using the form data D₂ in which the length L of the side between the adjacent corners 22a and the rising amount of the corners 22a are extended as compared with the device exposure pattern 21. Therefore, the corners 22a appear clearly on the monitor 5, and the operator can clearly recognize the positions of the corners 22a. Thus, the operator can drag the mouse to define the slit 6 not to overlap the corners 22a. Furthermore, since the length L of the side between the corners 22a is extended, the slit 6 can be sufficiently separated from the corners 22a, so that the line width of the pattern 22 can be measured without exploiting the rounded patterns near the corners 22a. Consequently, the line width of the monitor exposure pattern 22 is measured while eliminating the individual difference of operators, and thus the reproducibility of the measurement result can be increased.

Up to this, step S5 is completed and the process proceeds to step S6.

In step S6, by determining whether or not the line width of the monitor exposure pattern 21 measured in step S5 fall within the allowable range of the designed line width of the device exposure pattern 22, the line width of the device exposure pattern 22 are ensured by the dimension of the monitor exposure patterns 21. Then, when it is determined that the line width falls within the allowable range (YES), it is concluded that the line width of the device exposure pattern 22 also fall within the allowable range, and the exposure mask manufactured above shall be an acceptable product.

On the other hand, when it is determined that the line width does not fall within the allowable range (NO), it is concluded that the exposure mask is rejected, and an exposure mask is fabricated again.

Up to this, the primary steps in the method of manufacturing the exposure mask according to this embodiment are completed.

According to the embodiment described above, the monitor exposure pattern 22 are formed such that at least the corner 22a is made larger, number of the corner 22a is reduced, or the side between the corners 22a is extended as compared with the device exposure patterns 21, and the line width of the device exposure pattern 21 is ensured by the line width of the monitor exposure patterns 22.

According to this, as was shown in FIG. 20, the corners 22a of the monitor exposure pattern 22 clearly appear on the monitor 5 when measuring the line width of the monitor exposure pattern 22, so that the slit 6 can be set not to cover the corners 22a while confirming the positions of the corners 22a. In addition, by extending the side between the corners 22a, the slit 6 can be set sufficiently separate from the corners 22a, and this can prevent the line width measuring region defined by the slit 6 from incorporating the rounded patterns near the corners 22a. Consequently, in the present embodiment, the reproducibility in the measurement value of the line width of the monitor exposure pattern 22 can be improved, and thus the ensuring accuracy of the line width of the monitor exposure pattern 21 can be eventually increased.

The following table 2 is a summary of the investigated result about the reproducibility of line width measurement.

TABLE 2
Unit: nm

| Measured patterns | Average | Dispersion |
|---|---|---|
| Monitor exposure pattern 22 | 6.7 | 15.3 |
| Real pattern 23 | 6.9 | 11.0 |
| L/S pattern 24 | 11.3 | 10.2 |

In this investigation, the three measurement points A, B and C shown in FIG. 14 were measured in each of the 9 monitor regions II for the monitor exposure pattern 22 and the real patterns 23, and the average and the dispersion (maximum value−minimum value) of 27 (=3 points×9 areas) measurement values obtained by the measurement were calculated. On the other hand, the line width at only one point in each of the 9 monitor regions II was measured for the L/S patterns 24, and the average and the dispersion of 9 (=1 point×9 areas) measurement values obtained by the measurement were calculated.

As shown in table 2, the average values of line width of the L/S pattern 24 and the real pattern 23 deviated from each other about 4.5 nm due to different etching characteristic or the like caused by a difference in pattern density.

On the other hand, deviation of the average values of the line widths of the monitor exposure pattern 22 and the real pattern 23 is about 0.2 nm, which is a good result.

Further, with regard to the dispersion, it can be understood that the real pattern 23 is prominently poor and lacks reproducibility.

On the contrary, the dispersion of the monitor exposure pattern 22 is reduced as compared with that of the real pattern 23, and it can be understood that the reproducibility of line width measurement is improved.

Similarly, the dispersion is also reduced in the L/S pattern 24, to which the OPC process is not applied, as compared with the real patterns 23.

According to these investigation results, it is confirmed that the reproducibility of the line width is actually improved in the present embodiment.

The following table 3 is the one obtained by measuring the line width of the device exposure pattern 21 and monitor exposure pattern 22 shown in the FIG. 7 by the CD-SEM.

TABLE 3
Unit: nm

| | Device exposure | | | Monitor exposure | | |
|---|---|---|---|---|---|---|
| | pattern 21 | | | pattern 22 | | |
| Evaluation | A | B | C | A | B | C |
| items | 436(W) | 396(W) | 516(W) | 440(W) | 400(W) | 520(W) |
| Average value | 8.9 | 4.8 | 6.3 | 9.1 | 5.2 | 6.5 |
| (n = 25) | | | | | | |
| Measurement | 2.2 | 3.0 | 4.8 | 1.2 | 1.1 | 1.2 |
| reproducibility | | | | | | |
| (3σ) | | | | | | |

In the investigation of table 3, 25 times of line width measurement was performed in total for each of the three line width measurement points A, B and C of each patterns 21 and 22 as shown in FIG. 7, and the average values and the measurement reproducibility (3σ) were calculated. Note that the numerical values indicated by unit W in table 3 denotes the line widths at each measurement point A, B and C.

As shown in table 3, the measurement reproducibility becomes about 2.2 to 4.8 in the measurement of the line width of the device exposure pattern 21.

On the other hand, the measurement reproducibility became about 1.1 to 1.2 when the monitor exposure pattern 22 was measured as in the present embodiment, which makes it clear that the measurement reproducibility improved as compared with measuring the line width of the device exposure pattern 21.

### (3) Second Embodiment

In the first embodiment, steps S1 to S6 were performed as shown in FIG. 11. In this embodiment, only step S4 of the steps is different from the first embodiment, and the other steps are the same as the first embodiment. So, only step S4 will be explained and the explanation of the other steps will be omitted.

Step S4 is a process where each exposure pattern is actually fabricated on the quartz substrate to manufacture the exposure mask, and the half-tone phase shift mask was manufactured as the exposure mask in the first embodiment.

On the other hand, a digging Levenson mask is formed in this embodiment.

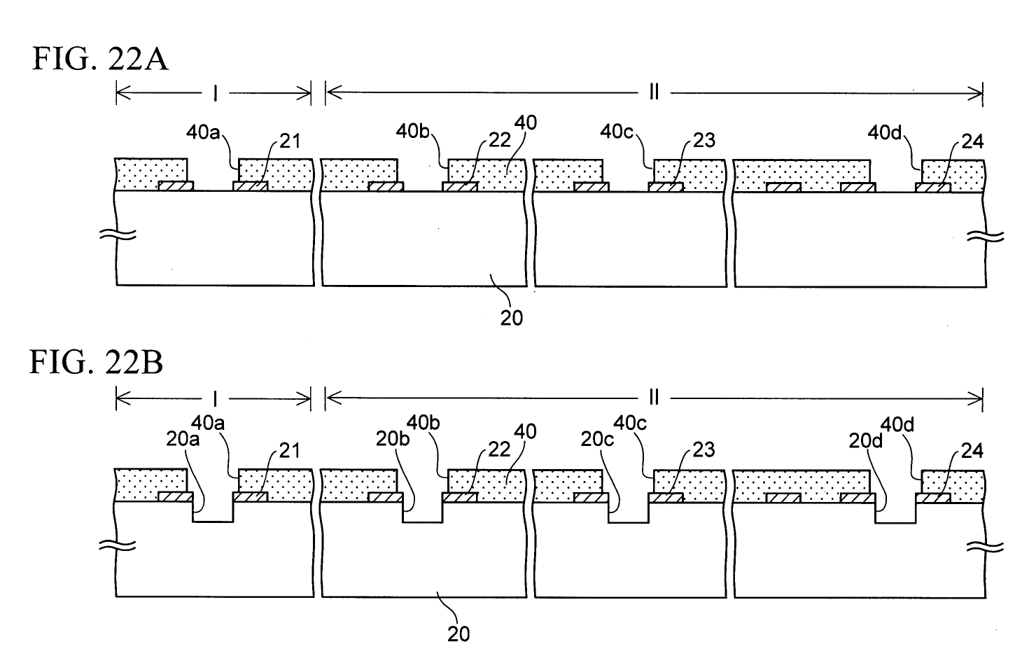

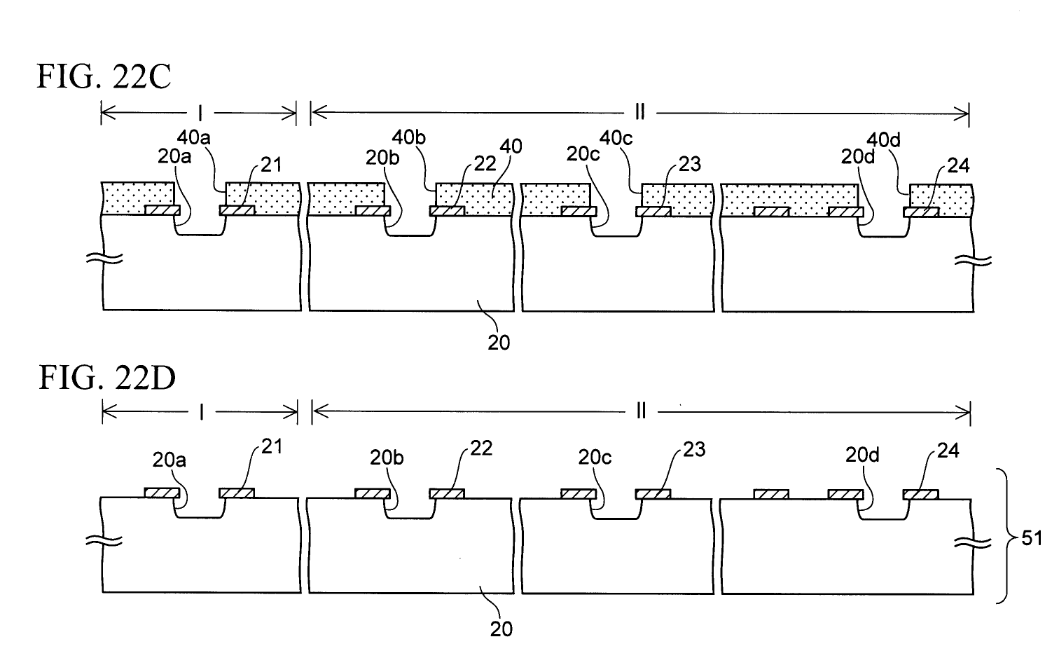

FIGS. 22A and 22B are the sectional views for explaining the method of manufacturing the exposure mask according to the second embodiment of the present invention. In these drawings, reference numerals same as those of the first embodiment are attached to elements explained in the first embodiment, and their explanation will be omitted in the following.

First of all, a process until the sectional structure shown in FIG. 22A will be explained.

Firstly, after forming a light-shielding chromium layer on the quartz substrate 20 by a sputtering method, the chromium layer is patterned into the light-shielding device exposure patterns 21, the monitor exposure patterns 22, the real patterns 23, and the L/S patterns 24. After that, a positive electron beam resist is formed on the quartz substrate 20 and each exposure patterns 21 to 24 in the thickness of about 400 nm by the spin coating method, and it is exposed and developed. Thus, as shown in FIG. 22A, a third resist pattern 40 including first to fourth windows 40a to 40d, where the quartz substrate 20 beside each exposure patterns 21 to 24 is exposed, is now formed.

Next, as shown in FIG. 22B, dry etching is performed to the quartz substrate 20 through the first to fourth windows 40a to 40b by RIE (Reactive Ion Etching) using CF₄ gas as etching gas, and first to fourth concave portions 20a to 20d for a shifter, which have the depth of about 70 nm, are formed on the quartz substrate 20. As the conditions for such etching, flow rate of CF₄ gas: 100 sccm, power of radio frequency electric power: 200 W, pressure: 6 Pa, and etching time: 240 seconds are employed.

Next, as shown in FIG. 22C, buffer hydrofluoric acid is used as etchant to perform isotropic wet etching to the quartz substrate 20 through the first to fourth windows 40a to 40d, the width and the depth of the first to fourth concave portions 20a to 20d are severally extended by about 100 nm, and the depth of each concave portion 20a to 20d is set to about 170 nm.

Then, as shown in FIG. 22D, the resist pattern 40 is removed by ashing with oxygen plasma and wet process, and the fundamental structure of an exposure mask 51 according to this embodiment is completed.

In the exposure mask 51, the quartz substrate 20 whose thickness became thin due to the first to fourth concave portions 20a to 20d becomes shifter portions. Then, a phase difference between exposure light having passed the shifter portions and the exposure light having passed the quartz substrate 20 where the first to fourth concave portions 20a to 20d were not formed and the thickness did not become thin becomes just 180 degrees, and thus the exposure patterns are projected onto the wafer (not shown) with the resolution of a diffraction limit or more.

After that, the process proceeds to steps S5 and S6 explained in the first embodiment, and the line widths of the device exposure patterns 21 are ensured by the actual measurement values of the line widths of the monitor exposure patterns 22 by the CD-SEM.

Accordingly, as explained in the first embodiment, the form data D₂ of the monitor exposure patterns 22, where the rising amount of the corners or the side length between the corners are extended comparing to the form data D₁ of the device exposure patterns 21, was obtained on step S2. Therefore, when measuring the line widths of the monitor exposure patterns 22 by the CD-SEM on step S5, the operator can easily confirm the corners of the monitor exposure patterns 22 on the monitor or can set the slit sufficiently separated from the corners 22, so that he/she can measure the line widths without exploiting the rounded patterns near the corners 22. As a result, the reproducibility of line width measurement is improved and the line widths of the device exposure patterns 21 can be ensured with high accuracy.

### (4) Third Embodiment

The digging Levenson mask was manufactured on step S4 of FIG. 11 in the second embodiment, but a regular exposure mask (binary mask) using no phase shift will be manufactured in this embodiment.

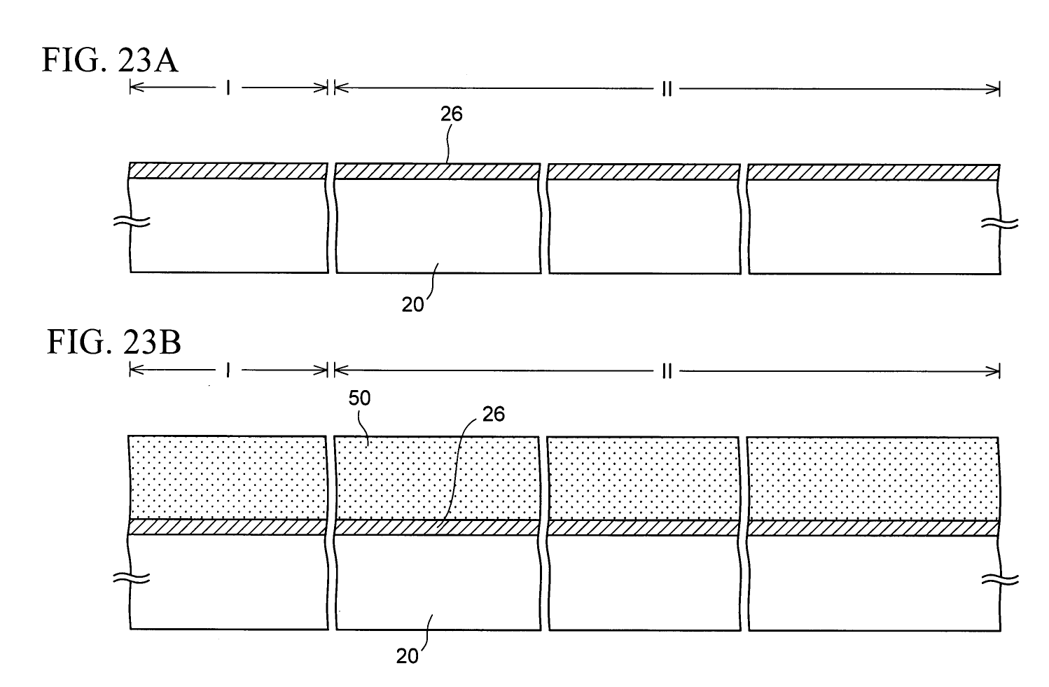

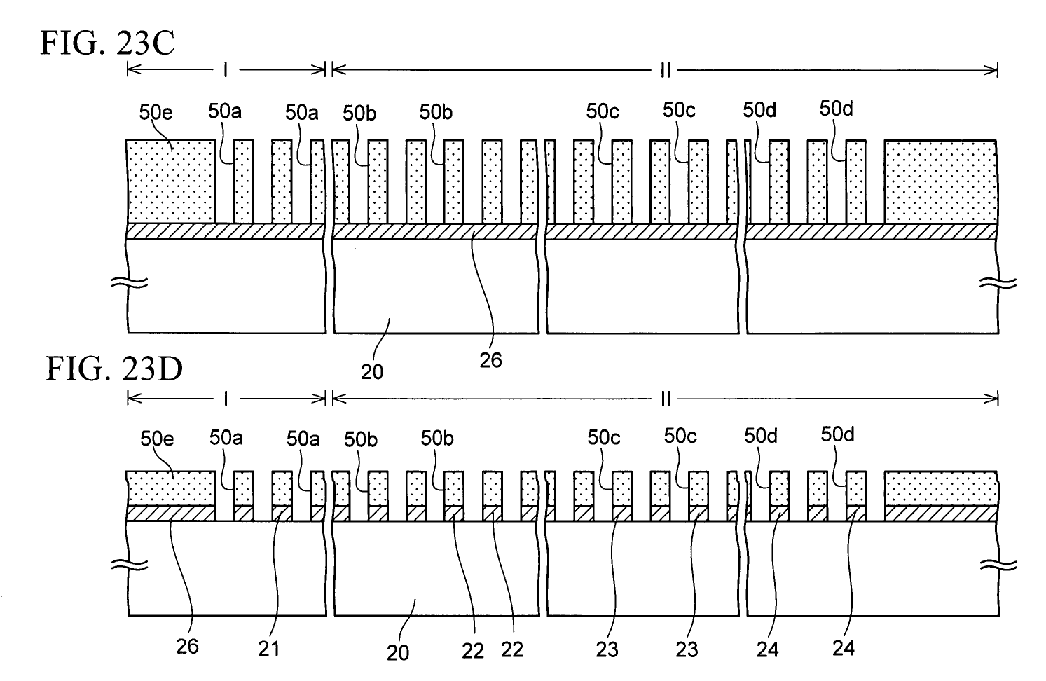

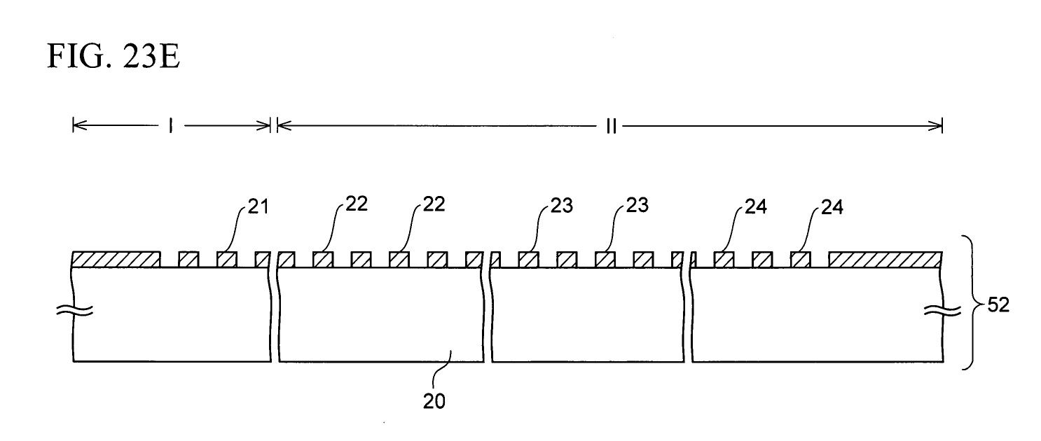

FIGS. 23A and 23B are the sectional views for explaining the method of manufacturing the exposure mask according to the third embodiment of the present invention.

First of all, description will be made for a process until the sectional structure shown in FIG. 23A.

Firstly, a chromium layer and a chromium oxide layer are formed in the thickness of about 100 nm in this order on the quartz substrate 20, and they are used as the light-shielding layer 26.

Next, as shown in FIG. 23B, a third positive electron beam resist 50 is formed in the thickness of about 400 nm on the light-shielding layer 26 by the spin coating method.

Subsequently, as shown in FIG. 23C, the third positive electron beam resist 50 is developed after it is exposed by the EB exposure apparatus by employing the same method explained in FIG. 19C of the first embodiment, and a fourth resist pattern 50e including first to fourth windows 50a to 50d is formed.

Next, as shown in FIG. 23D, after patterning the light-shielding layer 26 using the fourth resist pattern 50e as a mask by plasma etching using chlorine-based gas as etching gas, the light-shielding layer 26 that is left without being etched are used as the device exposure patterns 21 that do not transmit exposure light, the monitor exposure patterns 22, the real patterns 23, and the L/S patterns 24.

Subsequently, as shown in 23E, after removing the fourth resist pattern 50e by oxygen ashing, wet cleaning is performed for removing foreign objects, and the fundamental structure of an exposure mask 52 according to this embodiment is completed.

After that, the process proceeds to steps S5 and S6 explained in the first embodiment, and the line widths of the device exposure patterns 21 are ensured by the actual measurement values of the line widths of the monitor exposure patterns 22, which have been obtained by the CD-SEM.

Accordingly, due to the same reason explained in the first and second embodiments, the operator can easily confirm the corners of the monitor exposure patterns 22 on the monitor or can set the slit sufficiently separated from the corners 22, so that he/she can measure the line widths without exploiting the rounded patterns near the corners 22. As a result, the reproducibility of line width measurement is improved and the line widths of the device exposure patterns 21 can be ensured with high accuracy.

According to the present invention, since the monitor exposure patterns are fabricated such that at least the corners are made larger, the number of the corners is reduced, or the side between the corners is extended comparing to the device exposure patterns, the reproducibility of dimension measurement value of the monitor exposure pattern is increased, and ensuring accuracy of the line widths of the device exposure patterns can be eventually increased.

What is claimed is:

1. An exposure mask, comprising:
a transparent substrate;
a device exposure pattern formed in a device region of said transparent substrate, where a corner formed by a optical proximity effect being formed in at least one side of said device exposure pattern; and
a monitor exposure pattern formed in a monitor region of said transparent substrate, where, as compared with said device exposure pattern, a rising amount of said corner of said monitor exposure pattern being increased, or the number of said corner of said monitor exposure pattern being reduced, or a side of said monitor exposure pattern between said corners is extended.

2. The exposure mask according to claim 1, wherein
said device exposure pattern and said monitor exposure pattern are translucent phase shifters.

3. The exposure mask according to claim 2, wherein
said device exposure pattern and said monitor exposure pattern have a single layer structure or a multi-layer structure, which is made up of molybdenum-silicide compound or chromium compound.

4. The exposure mask according to claim 1, wherein
said device exposure pattern and said monitor exposure pattern are light-shielding pattern that do not transmit exposure light.

5. The exposure mask according to claim 4, wherein
said device exposure pattern and said monitor exposure pattern are made up of chromium.

6. The exposure mask according to claim 4, wherein
a first concave portion for phase shift is formed on said transparent substrate beside said device exposure pattern, and a second concave portion for phase shift is formed on said transparent substrate beside said monitor exposure pattern.

7. A method of manufacturing an exposure mask, comprising the steps of:
Obtaining a form data of a device exposure pattern, in which a corner is formed in at least one side, by performing an optical proximity effect correction for a form data of a device pattern;
obtaining an exposure data of a monitor exposure pattern, where, as compared with said device exposure pattern, a rising amount of said corner of said monitor exposure pattern being increased, or the number of said corner of said monitor exposure pattern being reduced, or a side of said monitor exposure pattern between said corners is extended;
patterning a film on a transparent substrate by lithography using each of said form data of said device exposure pattern and said monitor exposure pattern to form said device exposure pattern and said monitor exposure pattern;
measuring a dimension of said monitor exposure pattern by using a dimension sizer; and
ensuring a dimension of said device exposure pattern through the dimension of said monitor exposure mask by determining whether or not the dimension of said measured monitor exposure pattern falls within an allowable range of design dimension of said device exposure pattern.

8. The method of manufacturing an exposure mask according to claim 7, wherein
before forming said monitor exposure pattern, a step of observing a shape of a resist pattern formed from a projected image of said monitor exposure pattern by using a light intensity simulation, and confirming whether or not a pattern that is stripped in the course of manufacture is formed in said resist pattern is performed.

9. The method of manufacturing an exposure mask according to claim 7, wherein
the step of obtaining the form data of said device exposure pattern is performed by applying optical proximity effect correction using a first correction condition to the form data of said device pattern, and
the step of obtaining the form data of said monitor exposure pattern is performed by applying optical proximity effect correction using a second correction condition whose correction accuracy is rougher than said first correction condition to the form data of said device pattern.

10. The method of manufacturing an exposure mask according to claim 9, wherein
either a grid value that is a minimum unit for dimensional correction, or an interval between evaluating points of optical proximity effect is employed as said first and second correction conditions.

11. The method of manufacturing an exposure mask according to claim 9, wherein
a plurality of form data of said monitor exposure pattern are obtained by employing a plurality of said second correction conditions in the step of obtaining the form data of said monitor exposure pattern,
the step of extracting a form data, in which a side between said corners of said monitor exposure pattern is extended longer than a predetermined minimum value, from said plurality of form data is performed, and
said monitor exposure pattern is formed by using said extracted form data.

12. The method of manufacturing an exposure mask according to claim 11, wherein
the sum of the minimum length of a measuring region of said dimension sizer, a value twice the alignment error of the measuring region, and a value twice the rounding amount of the corner of the monitor exposure pattern, is employed as the minimum value of the length of the side between said corners.

13. The method of manufacturing an exposure mask according to claim 7, wherein
a SEM (Scanning Electron Microscope) is employed as said dimension sizer in the step of measuring said monitor exposure pattern.
